(19) United States
(12) Patent Application Publication
(10) Pub. No.: US 2006/0187717 A1
(43) Pub. Date: Aug. 24, 2006

(54) Robust face detection algorithm for real-time video sequence mobile drive with expansion capacity, stackable, mobile storage device and control circiut thereof

(76) Inventor: Chun-Yu Hsieh, Taichung City (TW)

Correspondence Address: J C PATENTS, INC., 4 VENTURE, SUITE 250, IRVINE, CA, 92618, US

(21) Appl. No.: 11/222,446

(22) Filed: Sep. 7, 2005

(30) Foreign Application Priority Data
Feb. 21, 2005 (TW) 94104990

(51) Int. Cl. G11C 16/04

(52) U.S. Cl. 365/185.33

(57) ABSTRACT

A stackable mobile storage device is provided, including a first mobile drive, at least a second mobile drive and a detachable module plugged between the first mobile drive and the second mobile drive to stack each other. The detachable module is composed of a male connector and a female connector. Especially, the second mobile drive is connected to a control unit of the first mobile drive by a switching unit when serving as a mobile drive for expanding capacity, to be enabled by the control of the first mobile drive. Therefore, the memory capacity of the second mobile drive can be added to the first mobile drive with more capacity to store more data.

### CROSS-REFERENCE TO RELATED APPLICATION

This application claims the priority benefit of Taiwan application serial no. 94104990, filed on Feb. 21, 2005. All disclosure of the Taiwan application is incorporated herein by reference.

### BACKGROUND OF THE INVENTION

1. Field of Invention

The present invention relates to a mobile storage device, more specifically, to a stackable mobile storage device.

2. Description of Related Art

Nowadays is information and multi-media age, a vast amount of information is digitized before being processed. Large size magnetic disks were used in the past, however, affected by magnetization effect, so that the magnetic disks were gradually eliminated due to its insufficient capacity, and small storage memories with larger capacity. A smaller storage medium with larger storage capacity and smaller volume has been introduced instead. Memory card, mobile drive (or walk drive) and micro hard drive in most common use have been developed based on the flash memory technology. In addition, these new type drives have advantages of easy carrying and convenient access.

Generally speaking, in the fabrication of the mobile drive, the mobile drive can mutually supports USB1.1 interface and USB2.0 interface to transport vast amount of data, so as to be compatible to a computer and its peripherals. And, the mobile drive requires no reading device (such as card reader), and features in plug-and-play. Moreover, since the capacity of the mobile drive is getting larger and larger, and it can store up to hundreds of compressed songs (such as MP3 music, etc.). Therefore, it can be very conveniently used as a walkman or pen recorder.

Remarkably, the capacity of the conventional single mobile drive is fixed, and no extension slot is designed on the drive. Thus, it is impossible to expand the capacity of the mobile drive when the user finds that the capacity is insufficient. As a result, one has to partially delete or completely erase the data on the original mobile drive, or transfer the data to a computer hard drive, so that new data can be stored on the mobile drive. This is very inconvenient. If the size of the new data is larger than the capacity of the mobile drive, the user has to use an alternative method or purchase a drive with lager capacity to solve this issue. However this will increase the cost. Therefore, the conventional single-capacity mobile drive is not convenient in various uses, and the capacity of each mobile drive can't be shared, thus its usability is affected.

### SUMMARY OF THE INVENTION

The object of the present invention is to provide a stackable mobile storage device which can expand the capacity of the mobile drive.

Another object of the present invention is to provide a control circuit by which the capacity of each mobile drive can be aggregated into a larger capacity to store more data conveniently.

The present invention provides a stackable mobile storage device including a first mobile drive, at least one second mobile drive and a detachable module. The first mobile drive includes a transmitting interface and a control unit, and the second mobile drive is stacked on the first mobile drive. Wherein, the first mobile drive has a first memory, while the second mobile drive has a second memory, and the capacity of the second memory can be added to the capacity of the first memory through a switching unit and is enabled by the control unit. In addition, the detachable module is coupled between the first and second mobile drives.

The present invention provides a control circuit which is suitable for using in a mobile storage device with a plurality of mobile drives. Each of the mobile drives has a memory, a control unit, a detachable module and a switching unit. Wherein, the detachable module has a male connector and a female connector, and the mobile drives are electrically coupled to each others by a manner of the combination of the male and the female connectors. In addition, the switching unit has a first switch, a second switch and a third switch, wherein the first switch is coupled between the control unit and the memory, and the second switch is coupled between the male connector and the memory, and the third switch is coupled between the female connector and the memory, so that the memory of each mobile drive is enabled by the control unit.

The present invention further provides a capacity expandable mobile drive which includes a base block, a transmitting interface, at least one connector and a switching unit. The base block includes a control unit and a memory, wherein the control unit is to control the reading and the writing operations on the memory. Moreover, the transmitting interface can be protruded out or hidden within the base block, and be electrically connected with the control unit. In addition, the connector is implemented on the base block to connect at least one second mobile drive which has a second memory. Furthermore, the switching unit has a plurality of switches wherein one of these switches is coupled between the control unit and the memory, and another one of these switches is coupled between the connector and the memory. As a result, the second memory of the second mobile drive can be enabled through the control unit.

According to the embodiment of the present invention, the above control unit for example includes a control chip and a circuit board, and the control chip is electrically connected to a transmitting interface through the circuit board. In addition, the transmitting interface is, for example, a universal serial bus (USB) interface. Moreover, the switching unit is, for example, an electronic three-way switch or a mechanical three-way switch.

The detachable module and the switching unit coupled between two mobile drives are used in the present invention to form a stackable mobile storage device with expandable capacity and its control circuit. Therefore, a single mobile drive can be used individually, and when a plurality of mobile drives are stacked together, the memories can be shared so as to increase the selectivity and manipulability of the mobile drive on using.

These and other exemplary embodiments, features, aspects, and advantages of the present invention will be described and become more apparent from the detailed description of exemplary embodiments when reading in conjunction with accompanying drawings.

### BRIEF DESCRIPTION OF THE DRAWINGS

FIG. 1A-FIG. 1B schematically illustrate the outer appearance and internal block diagram of a stackable mobile storage device, according to an embodiment of the present invention.

FIG. 2 schematically illustrates the block diagram of the internal equivalent circuit of the storage device of FIG. 1A.

FIG. 3 and FIG. 4 respectively schematically illustrate the outer appearance and the block diagram of the internal equivalent circuit of a stackable mobile storage device, according to an embodiment of the present invention.

FIG. 5 schematically illustrates the disassembling and assembling diagram of a stackable mobile storage device, according to another embodiment of the present invention.

FIG. 6 schematically illustrates the block diagram of the internal equivalent circuit of the stackable flash storage device of FIG. 5.

### DESCRIPTION OF THE PREFERRED EMBODIMENTS

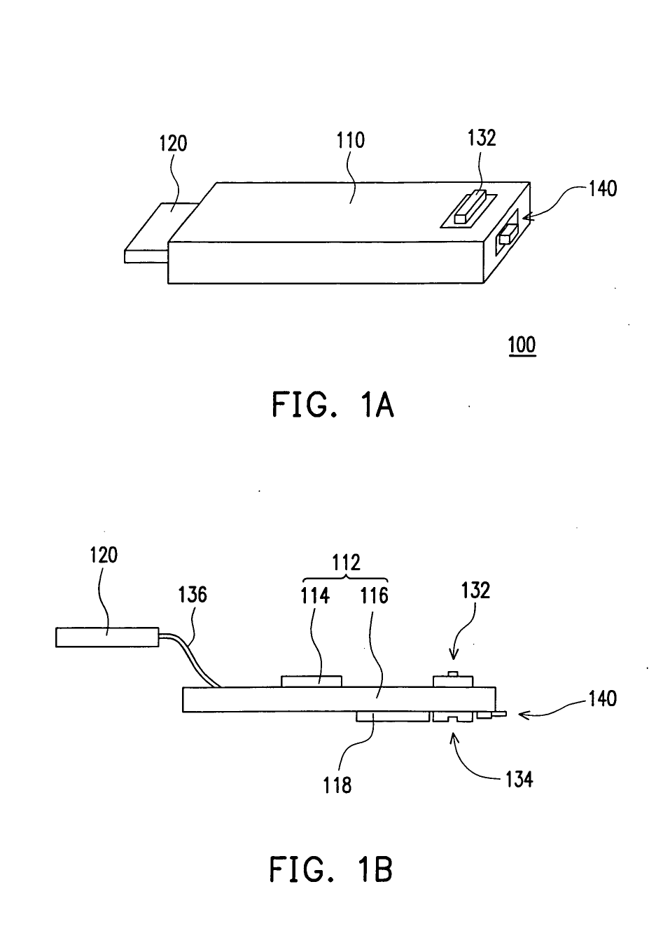

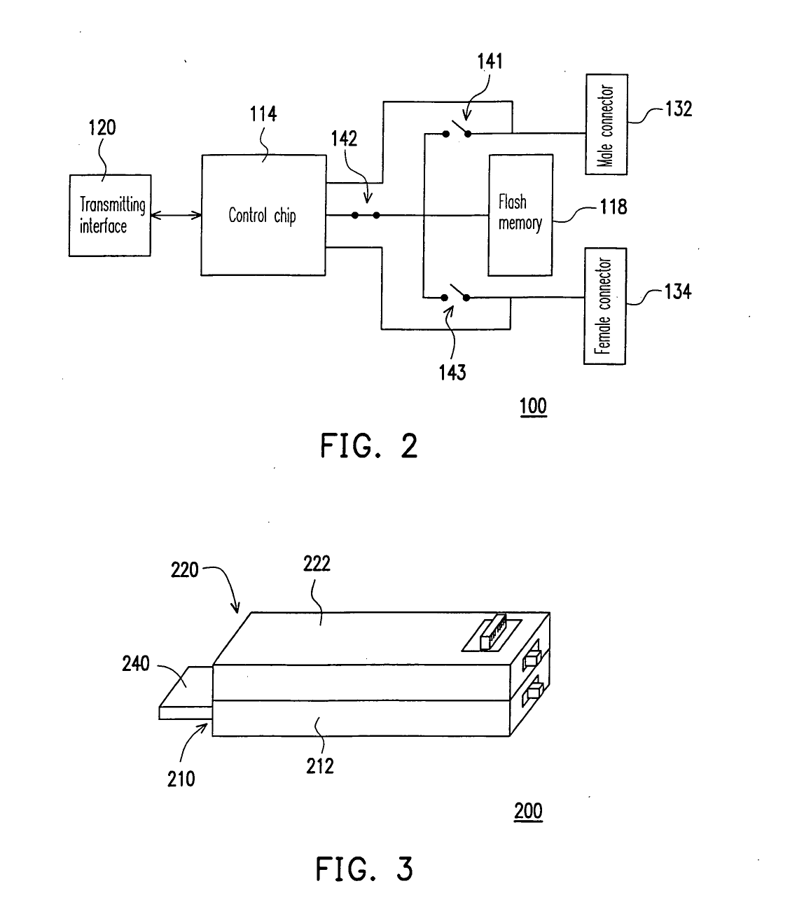

FIG. 1A-FIG. 1B schematically illustrate the outer appearance and internal block diagram of a stackable storage device, according to an embodiment of the present invention. And FIG. 2 schematically illustrates a block diagram of the internal equivalent circuit of the storage device of FIG. 1A. Referring to FIGS. 1A-1B, first, the stackable storage device 100 for example includes a base block 110, a transmitting interface 120, a male connector 132, a female connector 134 and a switching unit 140. Wherein, the base block 110 has a built-in control unit 112, such as control a chip 114, a circuit board 116 and the related parts thereof (not shown) etc. The control chip 114 can be electrically connected with the transmitting interface 120 through the circuit board 116 as shown in FIG. 1B. A usual transmitting interface 120 is, for example, a universal serial bus (USB) interface, an IEEE 1394 transmitting interface or other high speed transmitting interface, and preferably, the transmitting interface satisfying the specification of USB1.1 and USB2.0. In the present embodiment, although the transmitting interface 120 is protruded out of the base block 110, it can also be a retractable design (not shown) within the base block 110. The transmitting interface 120 can be electrically connected to the control unit 112 through a flat cable 136, so that the transmitting interface 120 can be hidden in the base block 110.

With referring to FIG. 1B, the base block 110 further includes a memory 118 inside, which includes for example a flash memory or other types of high capacity storage medium, implemented on the circuit board 116. The control chip 114 can access data on the memory 118. Remarkably, the switching unit 140 is implemented on the circuit board 116. In the equivalent circuit shown in FIG. 2, a switching unit 140 including a plurality of switches 141-143 or a single three-way switch (shown in FIG. 1A) is implemented between the control chip 114 and the memory 118 to switch the master/slave property of the storage device. When the storage device 100 is used individually, just by switching the switching unit 140 to the master connection end (close the switch 140 in the middle, and leave the upper and lower switches 141 and 143 open), the mobile drive can serve as a regular mobile drive. Moreover, to use a plurality of storage devices 100, just by combining the male connector 132 and the female connector 134 for switching its storage device to slave connection end (leaving the switch 142 in the middle open, and closing the upper and lower switches 141 and 143 respectively), the mobile drive can then serve as an expanded mobile drive to expand the capacity of the memory 118.

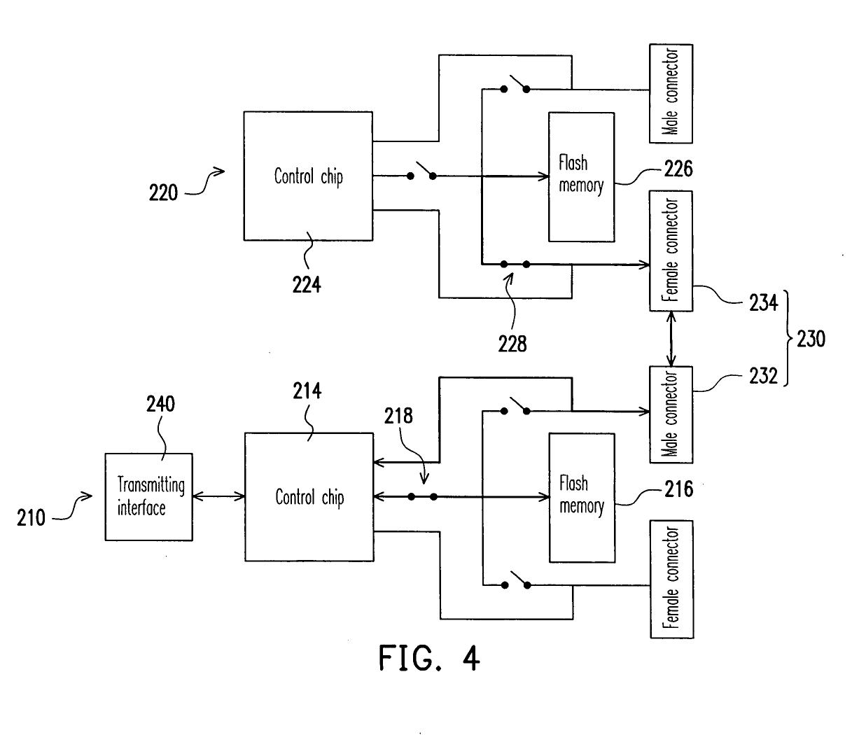

With referring to FIG. 3 and FIG. 4, both respectively show the diagram of the outer appearance and the block diagram of the internal equivalent circuit of a stackable mobile storage device of an embodiment of the present invention. The stackable mobile storage device 200 for example includes a first mobile drive 210, at least one second mobile drive 220 and a detachable module 230. The structure and function of the first mobile drive 210 are the same as those of the second mobile drive 220. Inside the base block, 212, 222, both have control chips 214, 224 and memories 216 and 226, respectively. The difference is that when the first mobile drive 210 serves as the mobile drive of the master control end, the switch 218 in the middle is electrically coupled between the control chip 214 and the memory 216, and leaves the circuit of upper and lower switches open. The second mobile drive 220 can only open the circuit of the middle and upper switches, and close the circuit of the lower switch 228 to connect the memory 226 and the corresponding female connector 234, so that the second mobile drive serves as a mobile drive with an expanded capacity. In addition, the first and the second mobile drives 210 and 220 can be stacked on top of each other through a detachable module 230 that combines the male connector 232 to the female connector 234. Specifically, the memory 226 of the second mobile drive 220 can be enabled by the control of the control chip 214 to store data.

In the above embodiment, the transmitting interface (not shown) can be hidden within the base block 222 to avoid hindering the use of the transmitting interface 240 of the first mobile drive 210 when the second mobile drive 220 serves as the capacity expanding mobile drive. Moreover, if the second mobile drive 220 is used individually, the user can just conveniently set the transmitting interface (not shown) to protrude out of the base block 222, thus enable the users to have various options of memory capacities without causing the insufficient memory problem.

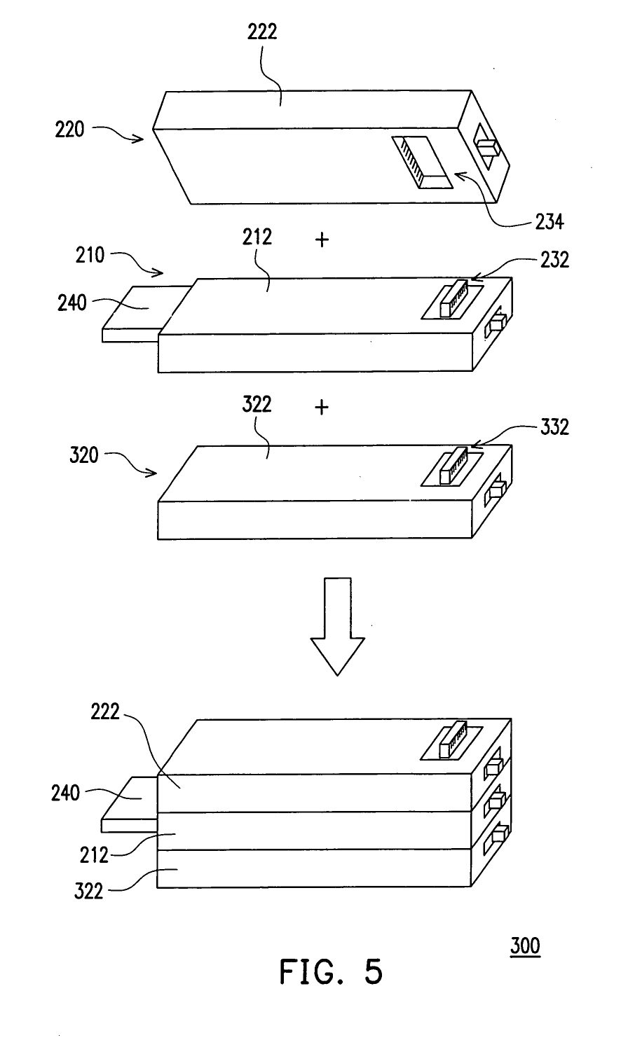

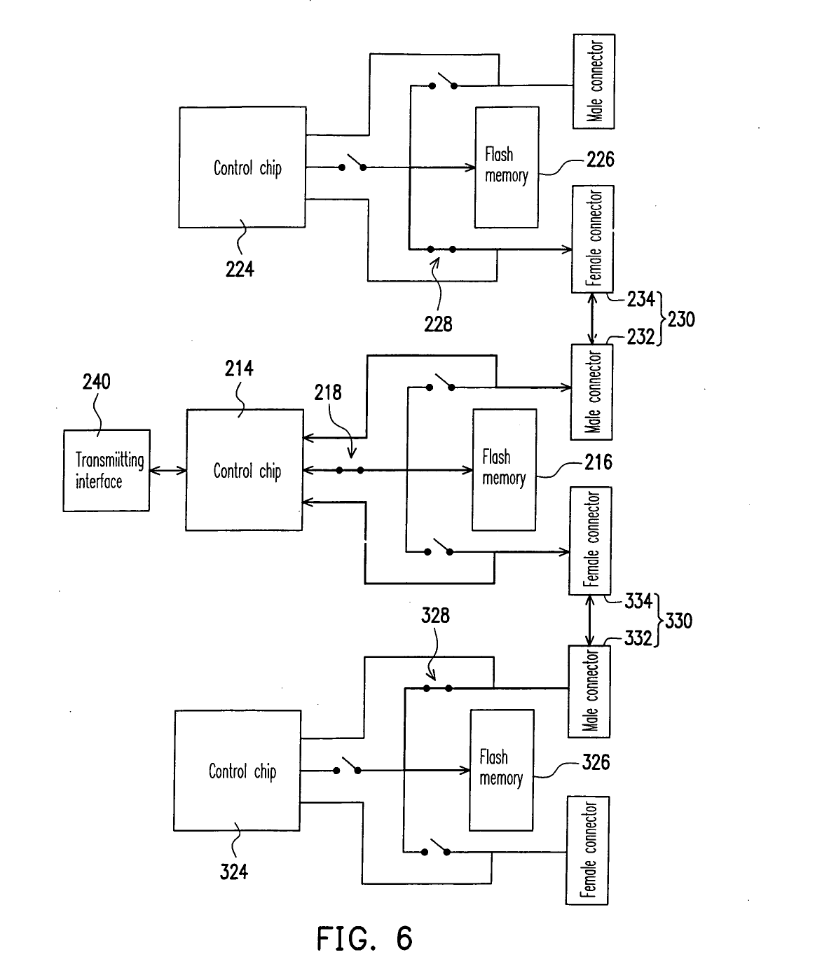

In addition, with referring to the FIG. 5 and FIG. 6, both illustrate the diagram of the outer appearance and the internal equivalent circuit about a stackable mobile storage device, with an embodiment of the present invention. The stackable mobile storage device 300 for example includes a first mobile drive 210, at least a second mobile drive 220, at least a third mobile drive 320 and two detachable modules 230 and 330. The structure and function of the first mobile drive 210 and the second mobile drive are as described in the previous embodiment, and there are also a control chip 324 and a memory 326 inside the base block 322 of the third mobile drive 320. Specifically, when the first and the second mobile drive 210, 220 are stacked on top of each other through a detachable module 230 between them, the first and the third mobile drives 210 and 320 can also be stacked on top of each other through another detachable module 330 (the combination of the male connector 332 and the female connector 334). In addition, the middle and the lower switches of the third mobile drive 320 are off, and the upper switch between the memory 326 and the corresponding male connector 332 is conducted, so that the whole of drive serves as a capacity expanding mobile drive, thus the mobile drive can be used very conveniently.

Similarly, the memory 326 of the third mobile drive 320 can also be enabled through the control chip 214 in the first mobile drive 210. Also and, the transmitting interface (not shown) can be hidden within the base block 322 to avoid hindering the use of the transmitting interface 240 in the first mobile drive 210 when the third mobile drive serves as a capacity expanding mobile drive. In addition, the transmitting interface (not shown) can be just protruded out of the base block 322 if the third mobile drive is used individually. The switch at the middle is conducted and the upper and lower switches are off. The reading and writing operations on the memory 326 are controlled by its own control unit 324.

It can be understood from the above descriptions, since a detachable module and a switching unit are used in the present invention to connect two mobile drives, a stackable mobile storage device and its control circuit with expandable memory capacity are formed. Wherein, each of the mobile drives is equipped with at least one connector (e.g. a male connector or a female connector, or both) which is capable of expanding the capacity of the memory, so that the capacity of the memory can be aggregated into a larger capacity. Moreover, the switching unit can be an electronic three-way switch, a mechanical three-way switch or a plurality of switches in combination.

In summary, the stackable mobile storage device and the control unit thereof of the present invention have at least the advantages as follows:

(1) Each mobile drive can be used individually, and a plurality of mobile drives can also be stacked on top of each other to share the memory to increase the selectivity and manipulability of the mobile drive.

(2) The transmitting interface can be hidden within the base block to avoid hindering the use of the transmitting interface in the master control end of the mobile drive when the mobile drive serves as a capacity expanding mobile drive.

While the present invention has been particularly shown and described with referring to exemplary embodiments thereof, it will be understood by those of ordinary skill in the art that various changes in form and details may be made therein without departing from the spirit and scope of the present invention as defined by the following claims.

What is claimed is:

1. A stackable flash storage device, comprising:
a first mobile drive, having a transmitting interface and a control unit;
at least a second mobile drive stacked on top of the first mobile drive, wherein the first mobile drive has a first memory while the second mobile drive has a second memory, and the memory capacity of the second memory is aggregated to the first memory capacity, and it is enabled by the control unit; and
a detachable module coupled between the first and the second mobile drive.

2. The stackable mobile storage device of claim 1, wherein the detachable module comprises a male connector and a female connector, and the first and second mobile drives are electrically coupled to each other through a combination of the male connector and the female connector.

3. The stackable flash storage device of claim 2, wherein the second mobile drive further comprises a transmitting interface and a control unit, and the transmitting interfaces of the first and second mobile drives are electrically connected to the corresponding control units through a flat cable.

4. The stackable mobile storage device of the claim 1, further comprising at least one third mobile drive stacked on top of the first mobile drive, and the third mobile drive comprising a third memory, a capacity of the third memory can be aggregated to the first memory capacity through another switching unit, and being enabled by the control unit.

5. The stackable flash storage device of the claim 1, wherein the control unit comprises a control chip and a circuit board, and control chip is electrically connected to the transmitting interface through the circuit board.

6. The stackable flash storage device of the claim 1, wherein the transmitting interface is a universal serial bus (USB) interface.

7. The stackable flash storage device of the claim 1, wherein the switching unit is an electronic three-way switch, a mechanical three-way switch or a combination of a plurality of switches.

8. A control circuit, suitable for using in a mobile storage device having a plurality of mobile drives, wherein each of the mobile drives comprises a memory, a control unit, a detachable module and a switching unit, the control circuit comprising:
a male connector and a female connector comprised in the detachable module, wherein by a combination of the male connector and the female connector, the mobile drives are electrically coupled with each other; and
a first switch, a second switch and a third switch comprised in the switching unit, wherein the first switch is coupled between the control unit and the memory, while the second switch is coupled between the male connector and the female connector, and the third switch is coupled between the female connector and the memory, so that the memories of the mobile drives are enabled through the control unit.

9. The control circuit of the claim 8, further comprising a transmitting interface implemented in each of the mobile drives, and being electrically coupled with the corresponding control unit.

10. The control circuit of the claim 9, wherein the transmitting interface is a universal serial bus (USB) interface.

11. The control circuit of the claim 9, wherein the transmitting interface is electrically coupled with the control unit through a flat cable.

12. The control circuit of the claim 8, wherein the control unit comprises a control chip and a circuit board, and the control chip is electrically connected to the detachable module through the circuit board.

13. The control circuit of the claim 8, wherein the switching unit is an electronic three-way switch, a mechanical three-way switch.

14. A capacity expandable mobile drive, comprising:
a base block, comprising a control unit and a memory, to control a plurality of operations of reading and writing on the memory;
a transmitting interface, being extruded out of the base block or hidden within the base block, and being electrically connected to the control unit;
at least a connector, implemented in the base block, to connect with at least a second mobile drive and a second memory; and
a switching unit, comprising a plurality of switches, wherein one of the switches is coupled between the control unit and the memory, while another one of the switches is coupled between the connector and the memory, so that the second memory of the second mobile drive is enabled through the control unit.

15. The capacity expandable mobile drive of claim 14, wherein the transmitting interface is a universal serial bus (USB) interface.

16. The capacity expandable mobile drive of claim 14, wherein the transmitting interface is electrically connected to the control unit through a flat cable.

17. The capacity expandable mobile drive of claim 14, wherein the control unit comprises a control chip and a circuit board, and the control chip is electrically connected to the detachable module through the circuit board.

18. The capacity expandable mobile drive of claim 14, wherein the switching unit is an electronic three-way switch or a mechanical three-way switch.
